(19) United States
(12) Patent Application Publication
(10) Pub. No.: US 2013/0104981 A1
(43) Pub. Date: May 2, 2013

(54) SYSTEMS AND METHODS FOR OPTICAL TRACKING

(71) Applicant: University of Delaware, Newark, DE (US)

(72) Inventors: Tian Gu, Newark, DE (US); Michael W. Haney, Oak Hill, VA (US); Juejun Hu, Newark, DE (US)

(73) Assignee: University of Delaware, Newark, DE (US)

(21) Appl. No.: 13/661,726

(22) Filed: Oct. 26, 2012

Related U.S. Application Data
(60) Provisional application No. 61/551,969, filed on Oct. 27, 2011.

(51) Int. Cl. H01L 31/0232; G02F 1/29; G02B 26/08

(52) U.S. Cl. 136/259; 359/196.1; 359/221.2; 359/226.3; 359/298

(57) ABSTRACT

Systems and methods for optical tracking are disclosed. One optical tracking system includes a first optical element configured to focus a light beam and a second optical element configured to redirect the focused light beam from the first optical element. The second optical element is configured to move in order to continuously receive the focused light beam during movement of the focused light beam. Another optical tracking system includes an optical element configured to redirect a light beam and a photosensitive material configured to change its optical properties when it receives the redirected light beam, in order to continuously redirect the light beam during movement of the light beam. The optical tracking methods employ the above-described optical tracking systems.

### CROSS-REFERENCE TO RELATED APPLICATIONS

The present application claims priority to U.S. Patent Application No. 61/551,969, filed Oct. 27, 2011, the contents of which are incorporated herein by reference in their entirety.

### FIELD OF THE INVENTION

The invention relates generally to the field of optics, and more particularly, to optical tracking systems and methods for use with photovoltaic devices.

### BACKGROUND OF THE INVENTION

In conventional high-efficiency photovoltaic applications, solar concentrators are used to concentrate a large area of sunlight onto the smaller photovoltaic panels. Due to the Earth's rotation, static (or immobile) concentrators are of limited utility. Instead, solar concentrators are desired that track the movement of the sun as it traverses the sky.

Conventionally, solar power devices track the sun's movement by rotating a solar concentrator and/or rotating an entire photovoltaic panel. However, these conventional “macro-scale” rotation techniques require excessive amounts of energy. Accordingly, systems and methods are desired that more efficiently perform optical tracking.

### SUMMARY OF THE INVENTION

Aspects of the present invention are directed to systems and methods for optical tracking.

In accordance with one aspect of the present invention, an optical tracking system is disclosed. The optical tracking system comprises first and second optical elements. The first optical element is configured to focus a light beam. The second optical element is configured to redirect the focused light beam from the first optical element. The second optical element is configured to move in order to continuously receive the focused light beam during movement of the focused light beam.

In accordance with another aspect of the present invention, an optical tracking method is disclosed. The optical tracking method comprises focusing a light beam with a first optical element, moving a second optical element in order to continuously receive the focused light beam during movement of the focused light beam, and redirecting the focused light beam with the second optical element.

In accordance with yet another aspect of the present invention, an optical tracking system is disclosed. The optical tracking system comprises an optical element and a photosensitive material. The optical element is configured to redirect a light beam. The photosensitive material is configured to change its optical properties when it receives the redirected light beam from the optical element in order to continuously redirect the light beam during movement of the light beam.

In accordance with still another aspect of the present invention, an optical tracking method is disclosed. The optical tracking method comprises redirecting a light beam with an optical element, receiving the redirected light beam with a photosensitive material configured to change its optical properties when it receives the redirected light beam, and redirecting the light beam with the photosensitive material.

### BRIEF DESCRIPTION OF THE DRAWINGS

The invention is best understood from the following detailed description when read in connection with the accompanying drawings, with like elements having the same reference numerals. When a plurality of similar elements are present, a single reference numeral may be assigned to the plurality of similar elements with a small letter designation referring to specific elements. When referring to the elements collectively or to a non-specific one or more of the elements, the small letter designation may be dropped. According to common practice, the various features of the drawings are not drawn to scale unless otherwise indicated. To the contrary, the dimensions of the various features may be expanded or reduced for clarity. Included in the drawings are the following figures:

FIG. 1 is a diagram illustrating an exemplary optical tracking system in accordance with aspects of the present invention;

FIG. 2 is a diagram illustrating exemplary movement of an optical element in the optical tracking system of FIG. 1;

FIG. 3 is a diagram illustrating an alternative optical element for the optical tracking system of FIG. 1;

FIG. 4 is a diagram illustrating exemplary movement of the optical element of FIG. 3;

FIG. 5 is a diagram illustrating another alternative optical element for the optical tracking system of FIG. 1;

FIG. 6 is a diagram illustrating an alternative path for the optical element in the optical tracking system of FIG. 1;

FIG. 7 is a diagram illustrating an alternative arrangement of the optical tracking system of FIG. 1;

FIG. 8 is a flowchart illustrating an exemplary optical tracking method in accordance with aspects of the present invention;

FIG. 9 is a diagram illustrating another exemplary optical tracking system in accordance with aspects of the present invention;

FIG. 10 is a diagram illustrating an alternative optical element for the optical tracking system of FIG. 9;

FIGS. 11A-11C are diagrams illustrating exemplary photosensitive materials for the optical tracking system of FIG. 9; and

FIG. 12 is a flowchart illustrating another exemplary optical tracking method in accordance with aspects of the present invention.

### DETAILED DESCRIPTION OF THE INVENTION

The embodiments of the invention described herein relate to optically tracking a light beam. The beam of light is optically tracked in order to continuously redirect light from a moving source (e.g., the sun) onto a fixed point (e.g., a photovoltaic device). As used herein, the term “continuously” is not intended to require that an action be performed at all times; rather, as used herein, the term “continuously” is merely intended to mean “for an unbroken length of time.” While the embodiments of the present invention are described herein with respect to solar power systems, it will be understood that the disclosed systems and methods may be usable in other suitable applications including, for example, optical interconnection, optical sensing, or any other area that may benefit from optically-controlled beam tracking and manipulation.

The systems and methods described herein are particularly suitable for optically tracking a light beam while minimizing the expenditure of energy. This may be accomplished by minimizing the mass of (or eliminating entirely) the components that are actively moved in order to accomplish the optical tracking. For example, the disclosed embodiments may employ an optical tweezing phenomenon in order to move an optical element using the light beam's own energy. For another example, the disclosed embodiments may be used to generate and move a cavitation bubble that functions as an optical element. For still another example, one or more actuators may be used to reposition a very small optical element (e.g., an optical microbead). The above examples desirably minimize the consumption of energy needed to continuously track a light beam with an optical element.

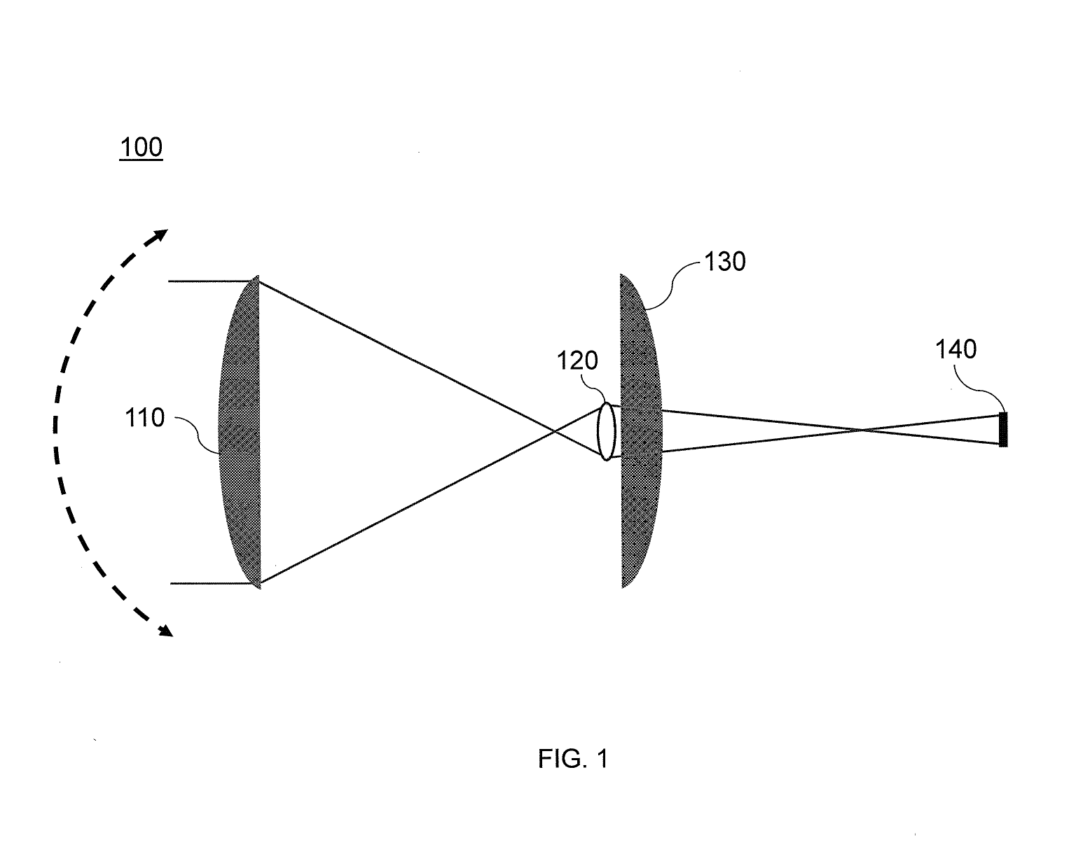

Referring now to the drawings, FIGS. 1-7 illustrate an exemplary optical tracking system 100 in accordance with aspects of the present invention. Optical tracking system 100 may be usable as part of a solar power system. As a general overview, optical tracking system 100 includes a first optical element 110 and a second optical element 120. Additional details of optical tracking system 100 are described herein.

First optical element 110 is configured to focus a beam of light. In an exemplary embodiment, first optical element 110 is a refractive lens, as shown in FIG. 1. However, first optical element 110 is not so limited. First optical element 110 may be any optical element adapted to collect light (e.g. focusing by refraction or reflection). Suitable optical elements for use as first optical elements 110 will be known to one of ordinary skill in the art from the description herein.

Second optical element 120 is configured to redirect the focused light beam from first optical element 110. As used herein, the term “redirect” is intended to encompass refracting, reflecting, deflecting, focusing, diverging, collimating, or any other action that changes the direction or focus of the light beam. As will be explained in greater detail below, second optical element 120 is configured to move in order to continuously receive the focused light beam from first optical element 110. In other words, during movement of the focused light beam (e.g. caused by movement of the light's source, as shown by dashed arrows in FIG. 1), second optical element 120 is configured to move with, or “optically track”, the focused light beam. Thereby, second optical element 120 also continuously redirects the focused light beam. Second optical element 120 may be, for example, a microlens, mirror, or curved reflector. Suitable optical elements for use as second optical element 120 may be selected based on the mechanism for moving second optical element 120, and as such, will also be explained below.

Optical tracking system 100 is not limited to the above described components, but may include alternative or additional components, as would be understood by one of ordinary skill in the art.

For example, optical tracking system may include a third optical element 130. Third optical element 130 is configured to focus or steer the redirected light beam from second optical element 120 onto a receiving element. In an exemplary embodiment, third optical element 130 is a refractive lens, as shown in FIG. 1. However, third optical element 130 is not so limited. Third optical element 130 may be any of the optical elements described above with respect to first optical element 110.

Optical tracking system 100 may also include a receiving element. In an exemplary embodiment, the receiving element is a photovoltaic cell 140. Photovoltaic cell 140 is positioned to receive the focused light from third optical element 130, as shown in FIG. 1. Suitable photovoltaic cells for use as photovoltaic cell 140 will be known to one of ordinary skill in the art from the description herein. In other embodiments, the receiving element may be other suitable components of optical systems, including, for example, optical signal receivers, optical fibers, or optical waveguides.

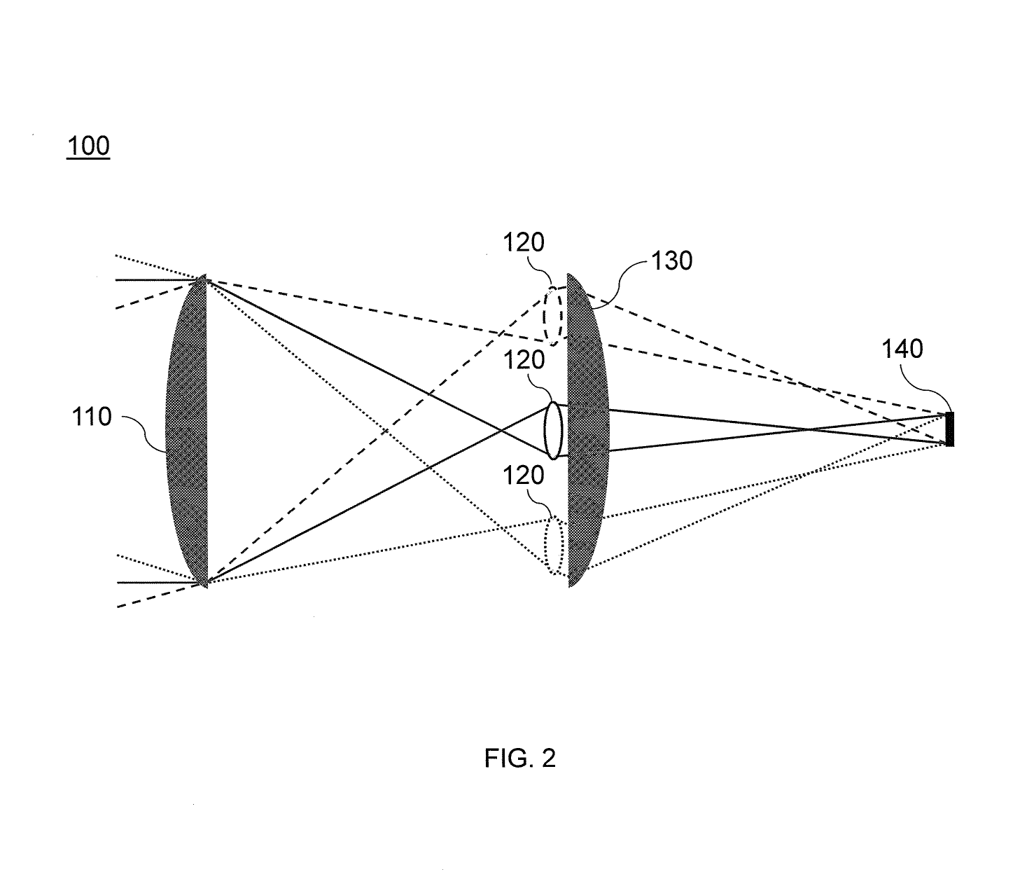

As set forth above, second optical element 120 is configured to move in order to continuously receive the focused light beam from first optical element 110. As shown in FIG. 2, for example, optical elements 110, 120, and 130 are designed such that as second optical element 120 moves and optically tracks the focused beam from first optical element 110, the focused light beam from third optical element 130 is continuously directed toward a fixed location. Exemplary positions of second optical element 120 during its movement are illustrated with dashed and dotted lines in FIG. 2. As shown in FIG. 2, regardless of the position of second optical element 120, the focused beam from third optical element 130 is continuously directed toward a fixed location. Desirably, photovoltaic cell 140 is positioned at the fixed location. Thus, regardless of the orientation of the light source (e.g. the sun), optical tracking system 100 continuously focuses the light beam (e.g. sunlight) directly onto photovoltaic cell 140.

As described above, optical tracking system 100 may be usable as part of a solar power system. In this embodiment, it may be expected that the solar power system will include solar power panels, each of which will comprise a plurality of photovoltaic cells. Accordingly, in solar power system applications, it may be desirable that each photovoltaic cell include its own optical tracking system 100 to focus sunlight independently onto the respective photovoltaic cell. However, in another embodiment, an optical collecting element (e.g., a light guide, an optical fiber, etc.) may be positioned at the receiver's location to collect the light. Light collected by the light guides from multiple optical tracking systems 100 may be subsequently joined together and directed onto a single photovoltaic cell.

The various mechanisms for moving second optical element 120 in the above manner will now be described. It will be understood by one of ordinary skill in the art that the invention is not limited to any particular mechanism for moving second optical element 120, and that a combination of mechanisms may be used, if desired.

In one embodiment, the second optical element 120 is configured to move via an optical tweezing mechanism generated by the focused light beam, as shown in FIGS. 1 and 2. The term “optical tweezing” refers to a phenomenon in which a highly focused light beam imparts a small attractive or repulsive force (i.e. a radiation pressure) on a microscopic object. The induced lift can be used to physically hold and move the object. The force on the object is dependent on the intensity of the light beam, the position of the beam's focal point, and the material of the object to be moved. In an exemplary embodiment, the second optical element 120 comprises an optical microbead configured to refract the focused light beam. The optical microbead may have a diameter of 100-800 microns, and may be formed from suitable plastic materials. In this embodiment, as the direction of the focused beam changes (e.g. due to the sun's movement), second optical element 120 is held or trapped within the focused light beam via optical tweezing, and is thus moved along with the focused light beam. In order to promote trapping of second optical element 120 within the focused light beam, second optical element 120 may be embedded in a layer of fluid. This may desirably lessen the force required to be generated via optical tweezing by making second optical element 120 more buoyant, and facilitate trapping and movement of second optical element 120.

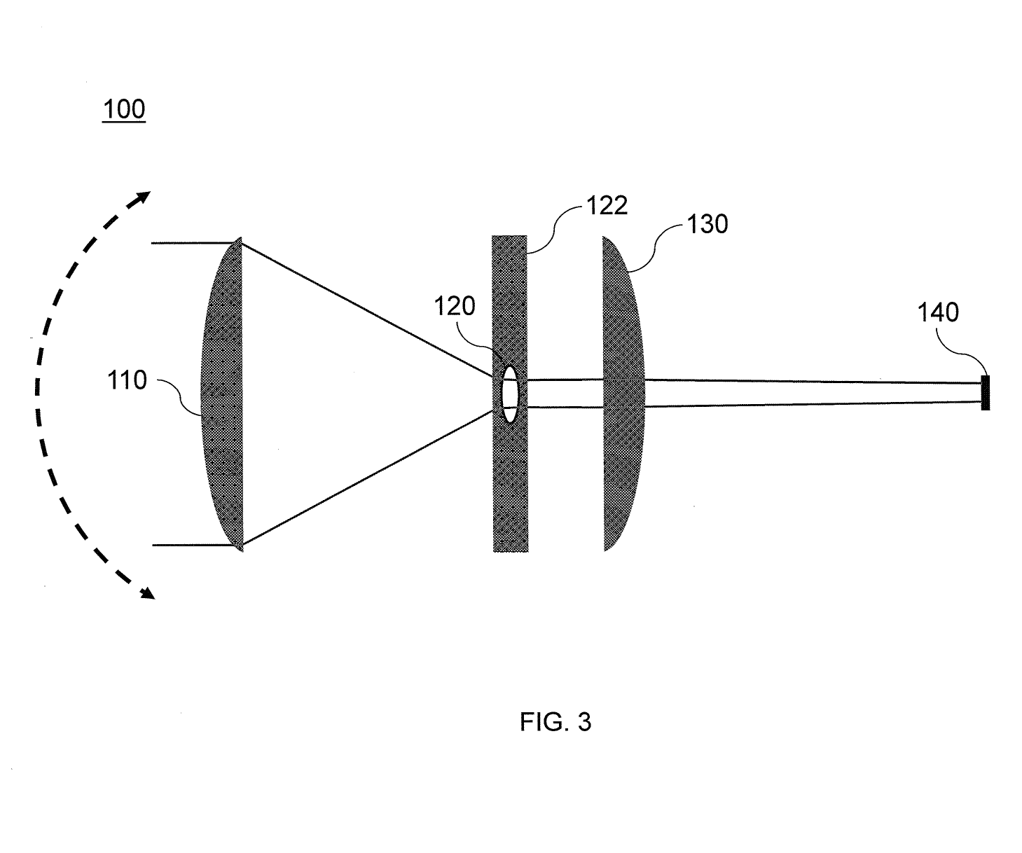

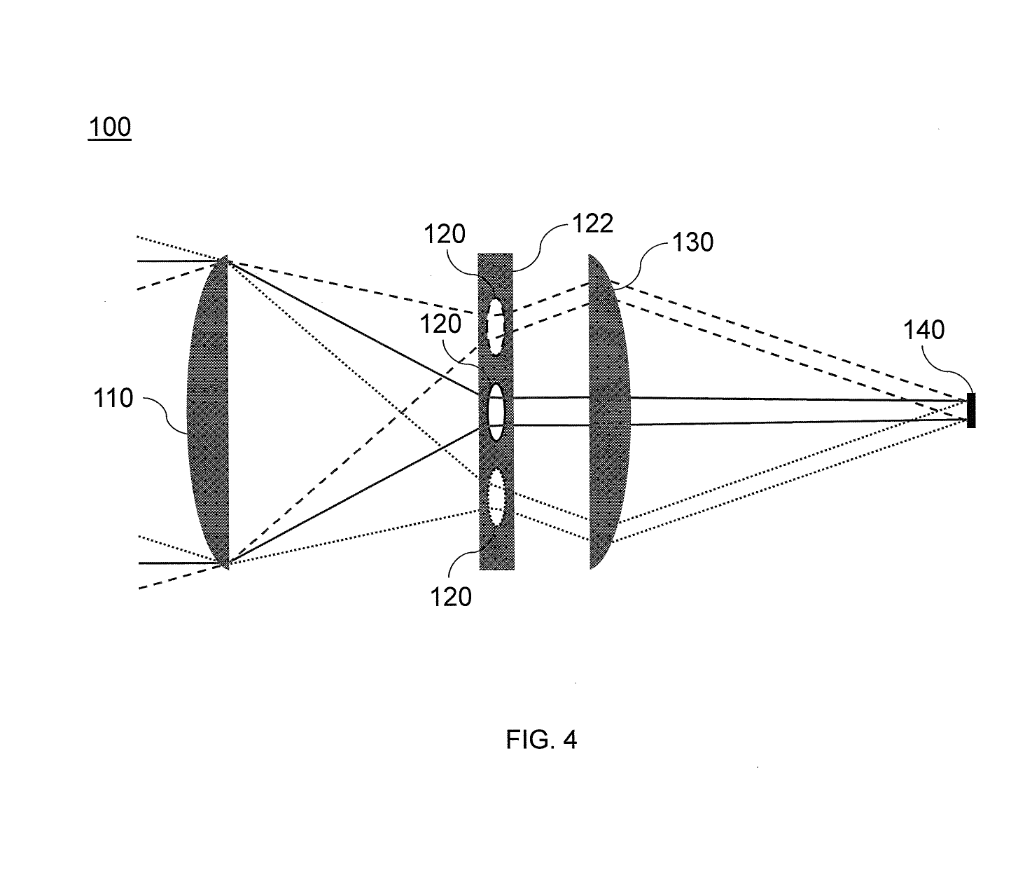

In another embodiment, the second optical element 120 is a cavitation bubble which is generated by the focused light beam, as shown in FIGS. 3 and 4. The term “cavitation bubble” refers to a persistent bubble that is generated when a focused light beam causes vaporization in a fluid, and when the resultant bubble is trapped in the fluid. The shape and size of the bubble is dependent on the intensity of the light beam, the position of the beam's focal point, and the fluid used. In an exemplary embodiment, optical tracking system 100 includes a fluid layer 122. The fluid layer may be between 10 microns and 1 mm thick, and may be formed from, for example, water. The container for fluid layer 122 may be shaped depending on the desired path for second optical element 120. For example, the container may have a planar cavity for straight paths or have a curved cavity for curved paths. As the light beam is focused on the fluid layer, it generates a small bubble that becomes trapped in fluid layer 122 at the location of the light beam impact. In this embodiment, the bubble serves as second optical element 120 (e.g., in the form of a negative lens). As the direction and position of the focused beam changes (e.g. due to the sun's movement), second optical element 120 moves through the fluid along with the focused light beam, i.e. by continuously tracking the portion of the beam that generates the bubble.

In a particular embodiment operating on the cavitation bubble design, first optical component 110 may be formed from the fluid or have an embedded fluid medium, so that the bubble that comprises second optical component 120 is created inside the first optical component 110 itself. The fluid may also carry some shapes that change the shape of the bubble as it is moved or re-generated by the focused light beam. For example, the thickness of the fluid medium may vary at different locations, so that the bubble is compressed or decompressed differently to realize different optical functions.

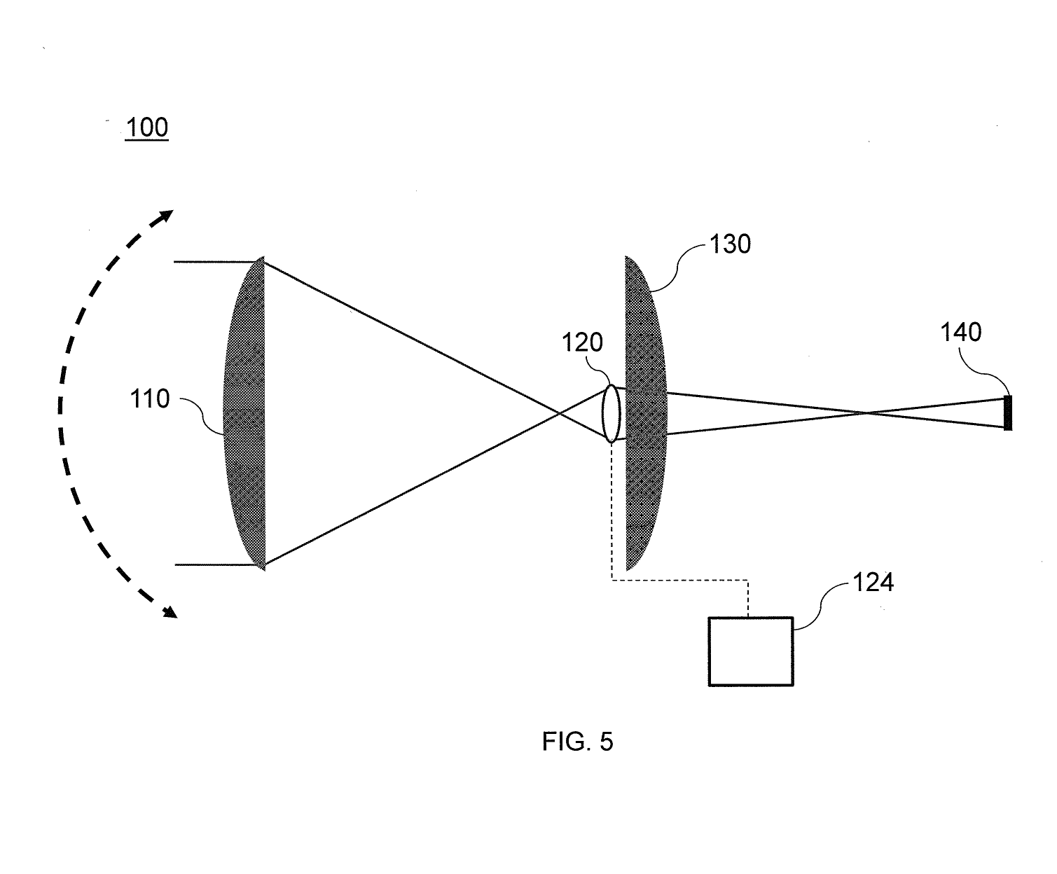

In yet another embodiment, an actuator 124 is configured to move the second optical element 120, as shown in FIG. 5. Actuator 124 may be coupled to second optical element 120 in order to maintain second optical element 120 within the focused light beam from first optical element 110. Suitable actuators for use as actuator 124 include microelectromechanical (MEMS) actuators, piezoelectric actuators, microfluidic actuators, or electrowetting actuators. Other suitable actuators will be known to one of ordinary skill in the art. In this embodiment, second optical element 120 is a small optical element, e.g., a microlens. Second optical element 120 is desirably small in order to minimize the amount of energy expended by actuator 124 in moving second optical element 120. Other suitable optical elements for use with this embodiment will be known to one of ordinary skill in the art.

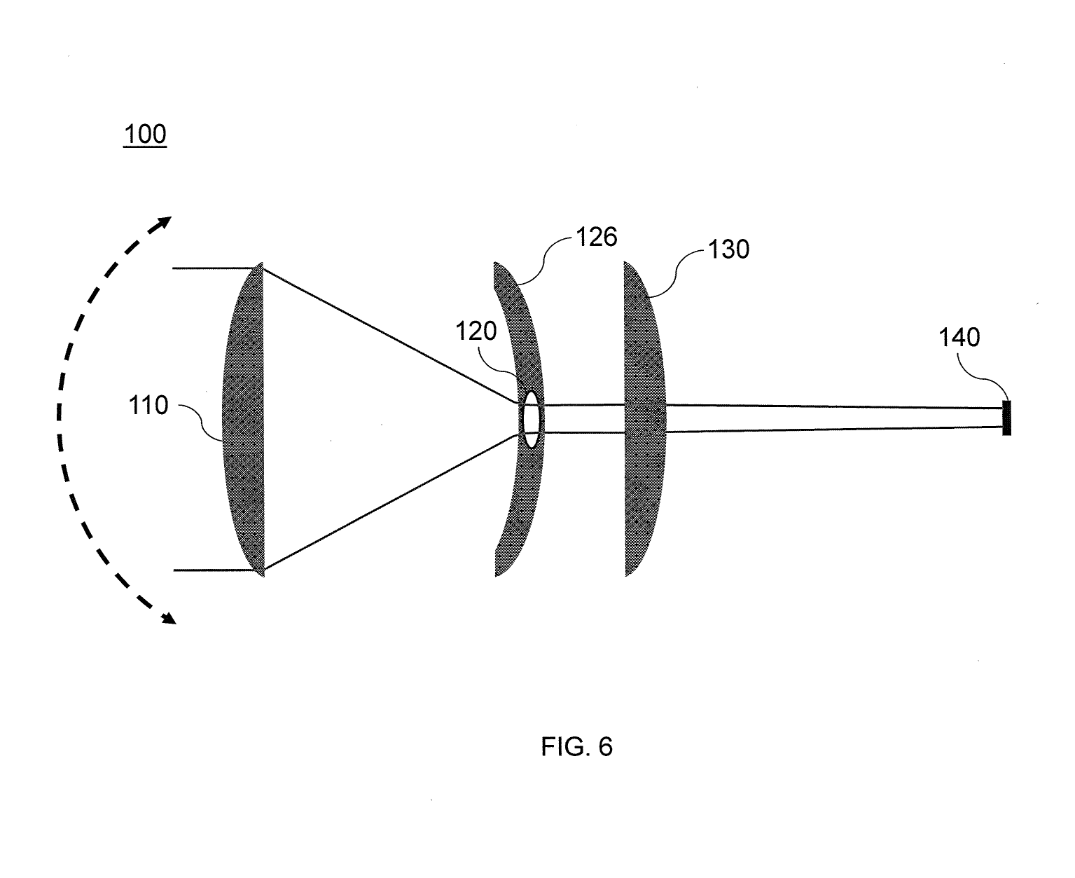

It may be desirable that optical tracking system 100 include a fixed path in order to direct the movement of second optical element 120. In an exemplary embodiment, third optical element 130 defines a path (i.e. on its front surface), such that second optical element 120 is confined to move along the path, as shown in FIGS. 1 and 2. The path may confine the movement of second optical element 120 in one dimension (e.g. left-right in FIG. 2) or in two dimensions (e.g. left-right and into-out of the page in FIG. 2). The acceptance angle translated from the path is desirably large enough to completely optically track the movement of the focused beam over a predetermined period of time (e.g., one day). In an exemplary embodiment, the acceptance angle is ±60° (assuming the sun moves at 15° per hour). As shown in FIGS. 1-5, the path may be planar in shape (for one-dimensional confinement), or may be a substantially straight line (for two-dimensional confinement). However, the path may have any suitable shape, as would be known to one of ordinary skill in the art. As shown in FIG. 6, path 126 may have a curved shape. Curved path 126 matches the focal plane of first optical element 110, in order to better facilitate the light manipulation process. Curved path 126 may be desirable based on the shape of the focused beam from first optical element 110, and the desired mechanism of movement of second optical element 120.

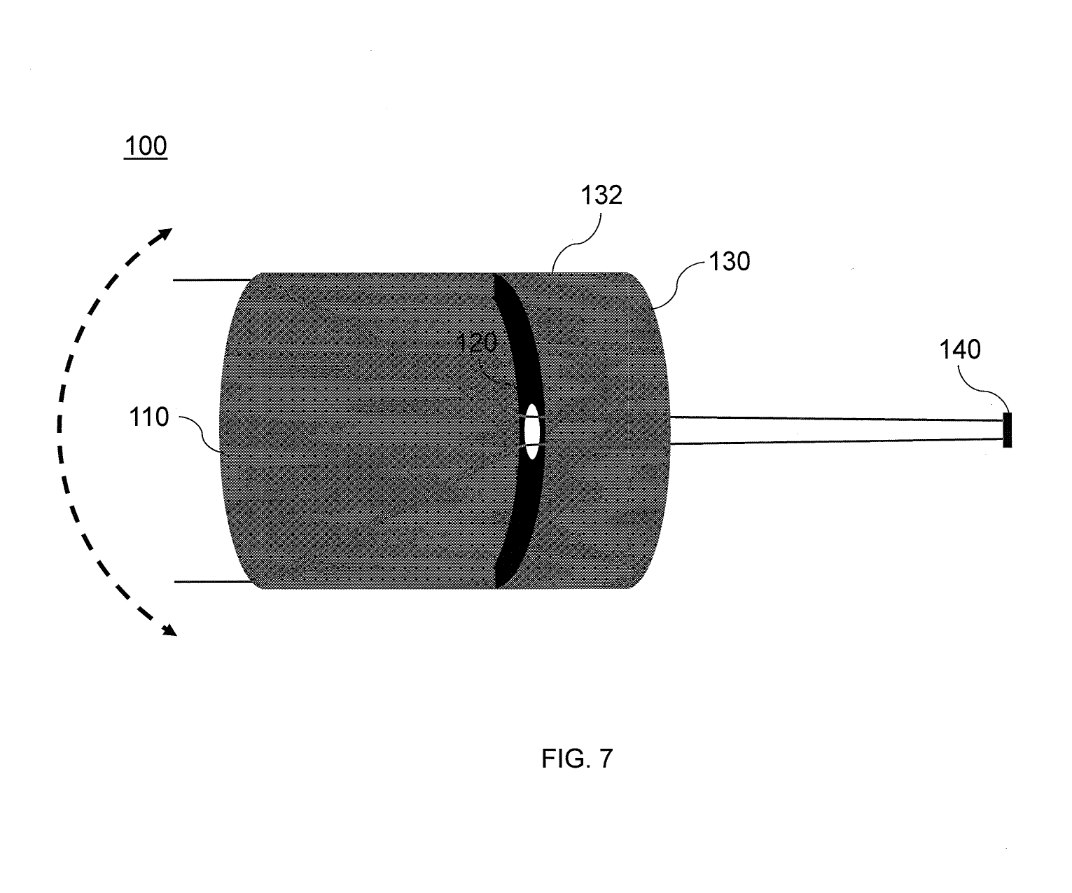

While first optical element 110 and third optical element 130 are illustrated separately in FIGS. 1-6, it will be understood that the invention is not so limited. In one embodiment, first optical element 110 and third optical element 130 may be integrally formed into a single body 132, as shown in FIG. 7. As shown in FIG. 7, second optical element 120 may be movably contained with body 132. Additionally, body 132 may define a path that confines the movement of second optical element 120 in one or more directions. It will be understood that this embodiment including integrally-formed body 132 may be usable with any of the above-described embodiments of second optical element 120, and any of the corresponding mechanisms of movement of second optical element 120.

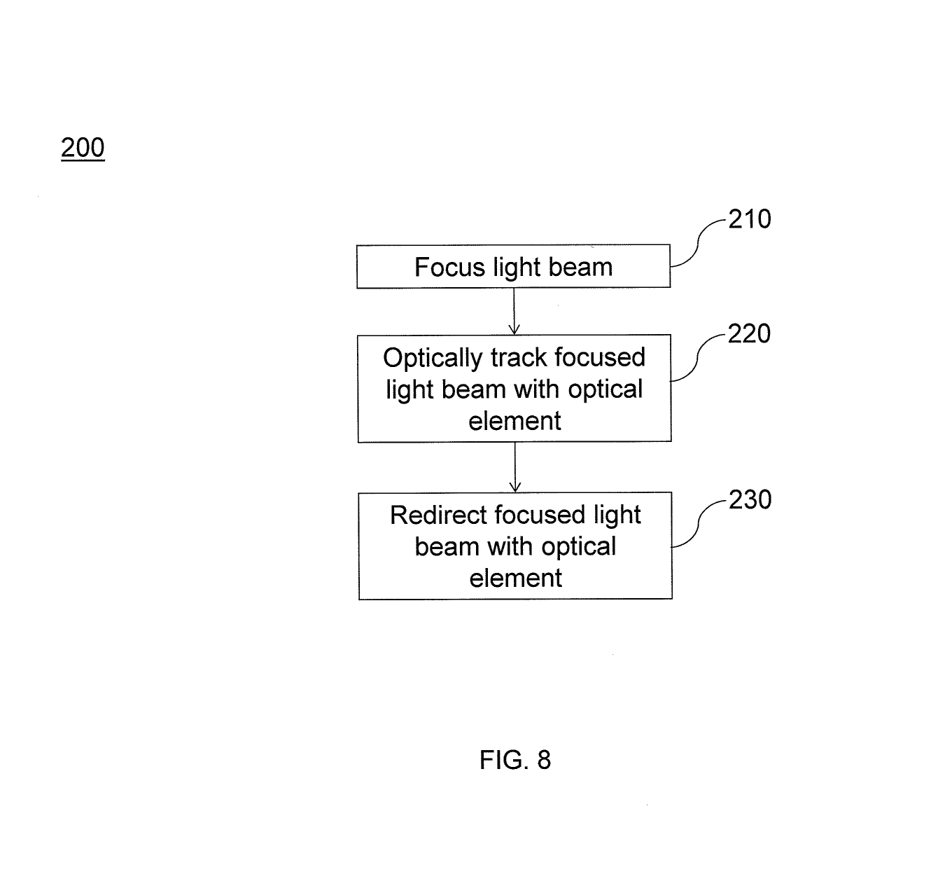

FIG. 8 illustrates an exemplary optical tracking method 200 in accordance with aspects of the present invention. Optical tracking method 200 may be performed by a solar power system. As a general overview, optical tracking method 200 includes focusing a light beam, optically tracking the focused light beam, and redirecting the focused light beam. Additional details of optical tracking method 200 are described herein with respect to optical tracking system 100.

In step 210, a light beam is focused. In an exemplary embodiment, first optical element 110 focuses an incident light beam (e.g., sunlight).

In step 220, the focused light beam is optically tracked. In an exemplary embodiment, second optical element 120 is moved in order to continuously receive the focused light beam during movement of the focused light beam. Second optical element 120 may be moved using any of the above-described mechanisms.

For example, this step may comprise moving second optical element 120 via an optical tweezing mechanism. This step may also comprise generating second optical element 120 by directing the focused light beam toward fluid layer 122, in order to create a bubble that functions as second optical element 120. This step may also comprise moving second optical element 120 with one or more actuators 124.

For another example, the second optical element 120 may be moved along a predefined path. Accordingly, this step may comprise confining the movement of second optical element 120 to a path, such as curved path 126.

In step 230, the focused light beam is redirected. In an exemplary embodiment, second optical element 120 continuously redirects the focused light beam from first optical element 110.

Optical tracking method 200 is not limited to the above described steps, but may include alternative or additional steps, as would be understood by one of ordinary skill in the art.

For example, optical tracking method 200 may further include focusing or steering the light beam after it is redirected. In an exemplary embodiment, third optical element 130 focuses the redirected light beam from second optical element 120. Still further, optical tracking method 200 may include a photovoltaic cell. In an exemplary embodiment, the focused light beam from third optical element 130 is received with photovoltaic cell 140.

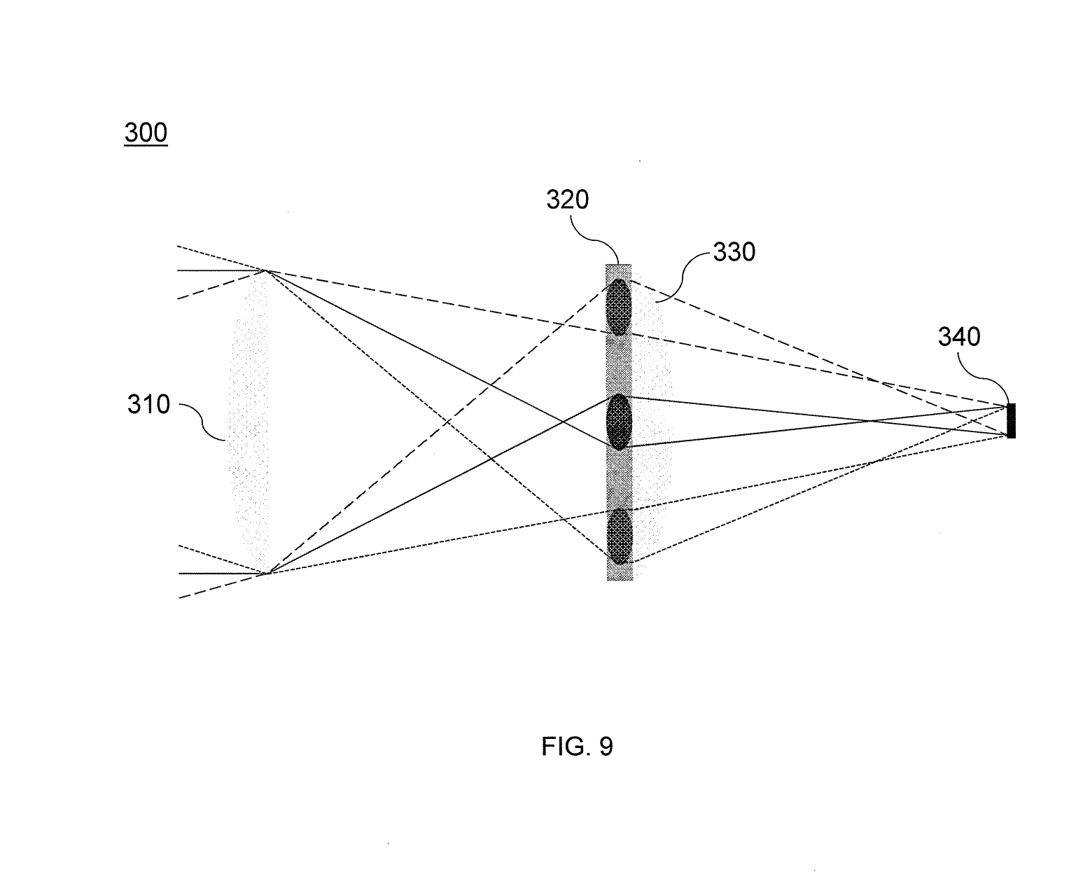

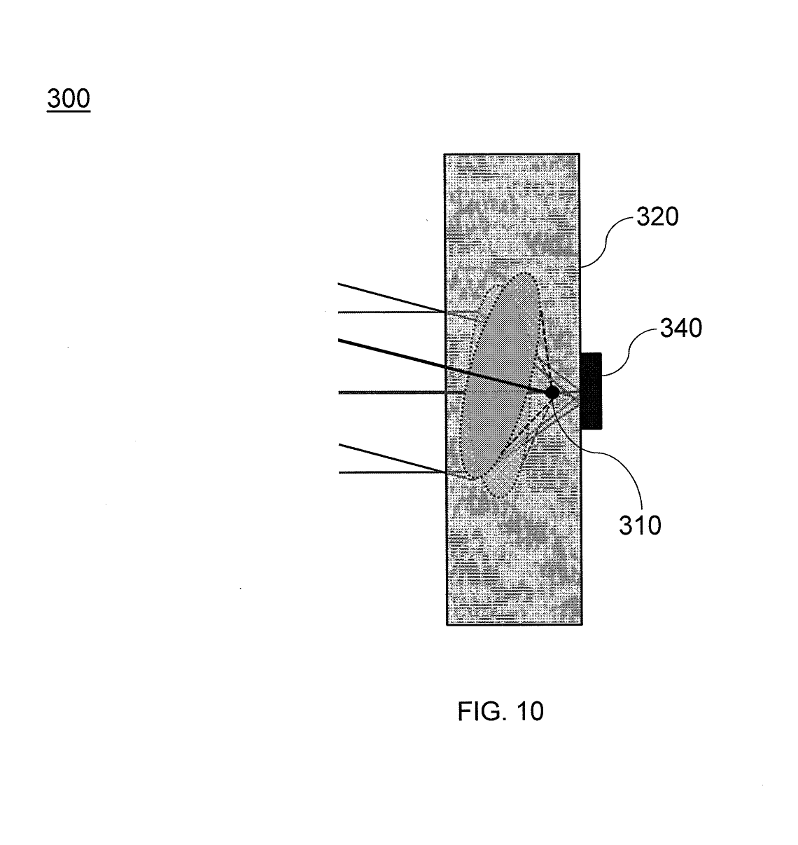

FIGS. 9 and 10 illustrate another exemplary optical tracking system 300 in accordance with aspects of the present invention. Optical tracking system 300 may also be usable as part of a solar power system. As a general overview, optical tracking system 300 includes an optical element 310 and a photosensitive material 320. Additional details of optical tracking system 300 are described herein.

Optical element 310 is configured to redirect a beam of light. In one exemplary embodiment, optical element 310 is a refractive lens configured to focus the light beam onto photosensitive material 320, as shown in FIG. 9. In this embodiment, optical element 310 may be any of the optical elements described above with respect to first optical element 110.

In another exemplary embodiment, optical element 310 is a reflective element, as shown in FIG. 10. The reflective element is embedded within or formed on the surface of photosensitive material 320, and is configured to reflect the light beam within photosensitive material 320, as shown in FIG. 10. The reflective element serves as one or more local reflective sites which form a local induced optical element under the illumination of the light beam. By properly arranging the location of the reflective element or designing the manner by which it reflects, the local induced optical element can be utilized to direct the light beam to a desired location or to control the properties of the output light (propagation direction, divergence, intensity, irradiance pattern, etc.). Suitable reflective elements for use as optical element 310 in this embodiment include, for example, metal nano-particles, spheres, defects, reflective coatings, reflective structured surface, and/or macro-reflectors (e.g., mirrors). Other suitable reflective elements will be known to one of ordinary skill in the art from the description herein.

Photosensitive material 320 is configured to change its optical properties when it receives the redirected light beam from optical element 310. By changing its optical properties when it receives the redirected light beam, photosensitive material 320 is able to continuously redirect the light beam regardless of any movement of the light beam. In other words, portions of photosensitive material 320 change their optical properties, and thereby form “effective optical elements” that can move with, or “optically track”, the focused light beam.

In an exemplary embodiment, the photosensitive material 320 changes its refractive index when subjected to the light beam (e.g., via the photorefractive effect). The passage of the light beam through photosensitive material 320 locally changes the material's refractive index, which induces an effective optical lens (such as a graded-index medium that gives an input light beam a non-uniform phase change, forming the effective lens) inside photosensitive material 320. This varies its optical functionality according to the variance of the redirected light beam. For a focused light beam, for instance, the maximum change of the refractive index happens at the center of the focused beam where it has the highest intensity. The photosensitive material therefore behaves as a graded-index medium with induced local refractive index variance, achieving functionalities such as self-focusing (an induced effective lens) or self-trapping (an induced effective light guide). In a self-trapping process, the diffraction of a beam is compensated by the self-focusing effect so that the light is always guided in a confined region.

In an exemplary embodiment, photosensitive material comprises a liquid crystal elastomer (LCE). The LCE may incorporate cis/trans photo-reversible isomeric moieties, such as azobenzene or stilbene, into the backbone of a polymer network to achieve photo-reversible actuation. The photo-induced switching from the trans- to cis-isomer may result in a significant change in molecular distances that induces a macroscopic volume change, which may be usable to redirect the light beam.

It will be understood that other optical phenomena may be used for forming the effective optical element alternatively or in addition to the above-described mechanisms. Such mechanisms include, for example, thermal effects, photochromic effects, electronic polarization, molecular orientation, eletrostriction, or saturated atomic absorption. Still other exemplary mechanisms for forming the effective optical element include using a localized melting of low-melting point materials (e.g. the phase change alloys), which under concentrated solar radiation can melt and form a little lens-shape puddle with index change; or using photosensitive liquid crystals whose molecular orientation can be modified by solar radiation, and thereby leading to local index change. Suitable materials for use as photosensitive material 320 include, for example, non-linear polymers whose indices of refraction change as a function of the intensity of the incident light. Other suitable materials will be known to one of ordinary skill in the art from the description herein.

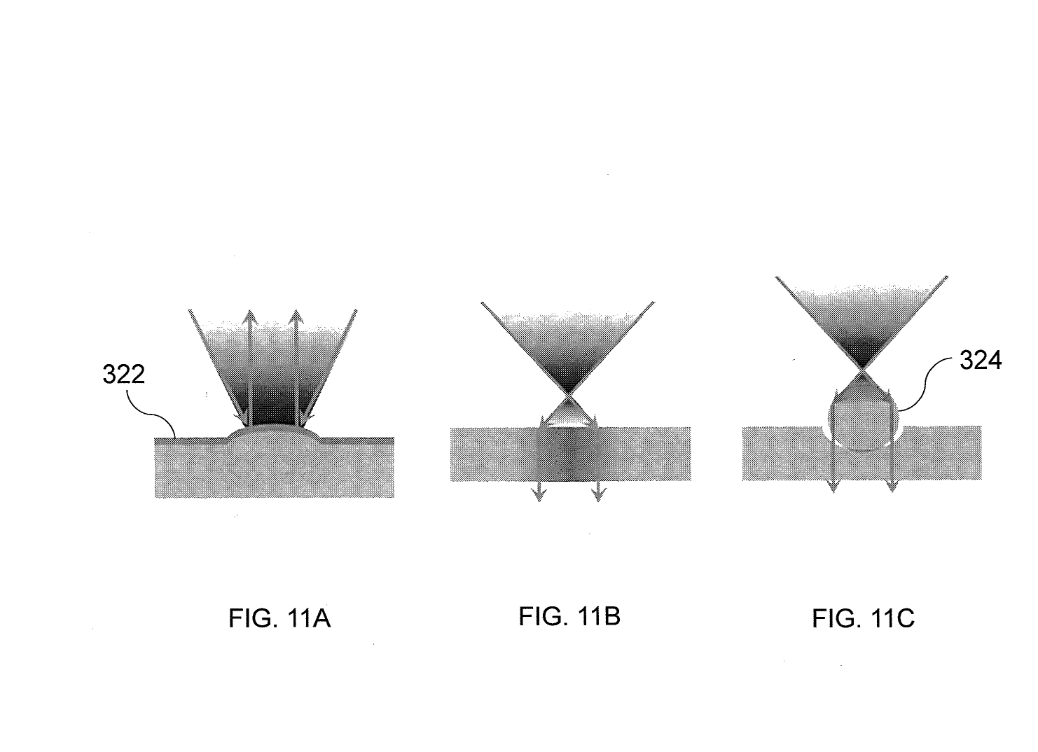

FIGS. 11A-11C illustrate exemplary mechanisms for modifying the optical properties of photosensitive material 320 in accordance with aspects of the present invention.

As shown in FIG. 11A, photosensitive material 320 may have a reflective coating 322 formed on a surface thereof. In this embodiment, the photosensitive material 320 expands or contracts in proportion to the intensity of the incident light mirror. When the focused light beam is incident on photosensitive material 320, photosensitive material 320 is configured to expand or contract in order to create a convex or concave mirror on the surface thereof. Reflective coating 322 desirably has high spectral reflectance across the solar spectrum, high temperature and optical stability, and good adhesion with photosensitive material 320. In an exemplary embodiment, reflective coating 322 comprises a multi-layer dielectric/metal hybrid coating. The multi-layers may be deposited via evaporation or sputtering.

As shown in FIG. 11B, photosensitive material 320 may be configured to refract the focused light beam, e.g., via the photorefractive effect. In other words, a lens forms in photosensitive material 320 due to the photorefractive affect.

As shown in FIG. 11C, photosensitive material 320 may include a freely moving lens 324 on a surface thereof. In this embodiment, photo-induced shape deformation of photosensitive material 320 is used to actuate micro-lenses and enable self-tracking. When illuminated, photosensitive material 320 contracts and forms a depression or dimple. The lens 324 is forced by gravity to remain in the depression, and thereby, moves across the surface of photosensitive material 320 as the depression created by the focused light beam moves. The shape and size of the depression may be selected based on the elastic properties and photo-response of photosensitive material 320. In this embodiment, it may be desirable to include a plurality of lenses 324 on the surface of photosensitive material 320 to insure that the focused light beam “picks up” and is redirected by a lens.

Optical tracking system 300 is not limited to the above described components, but may include alternative or additional components, as would be understood by one of ordinary skill in the art.

For example, optical tracking system may include an additional optical element 330, as shown in FIG. 9. The additional optical element 330 is configured to focus or steer the redirected light beam from the photosensitive material 320. In an exemplary embodiment, the additional optical element 330 is a refractive lens, as shown in FIG. 9. However, additional optical element 330 is not so limited. Additional optical element 330 may be any of the optical elements described above with respect to first optical element 130.

Optical tracking system 300 may also include a photovoltaic cell 340. Photovoltaic cell 340 is positioned to receive the focused light from additional optical element 330, as shown in FIG. 9, or directly from photosensitive material 320, as shown in FIG. 10. Suitable photovoltaic cells for use as photovoltaic cell 340 will be known to one of ordinary skill in the art from the description herein.

As similarly described above with respect to optical tracking system 100, optical element 310 and photosensitive material 320 are designed such that as photosensitive material 320 changes in a way that optically tracks the focused beam from optical element 310, the redirected light beam from photosensitive material 320 is continuously directed toward a fixed point (either with or without the use of additional optical element 330). Exemplary changes to photosensitive material 320 during its exposure to the focused light beam are illustrated with dashed and dotted lines in FIGS. 9 and 10. As shown in FIG. 9, regardless of the direction of the focused light beam, the changes in photosensitive material 320 redirect the light beam toward a fixed point. Desirably, photovoltaic cell 340 is positioned at the fixed point. Thus, regardless of the orientation of the light source (e.g. the sun), optical tracking system 300 continuously focuses or redirects the light beam (e.g. sunlight) directly onto photovoltaic cell 340.

As described above, optical tracking system 300 may be usable as part of a solar power system. In this embodiment, it may be desirable that each photovoltaic cell include its own optical tracking system 300, as described above with respect to optical tracking system 100. In another embodiment, an optical collecting element (e.g., a light guide, an optical fiber, etc.) may be positioned at the receiver's location to collect the light. Light collected by the light guides from multiple optical tracking systems 100 may be subsequently joined together and directed onto a single photovoltaic cell.

Optical tracking system 300 may also be used in any of the ways and with any of the components discussed above with respect to optical tracking system 100. In particular, photosensitive material 320 may be substituted for second optical element 120 in any of the above-described embodiments of optical tracking system 100.

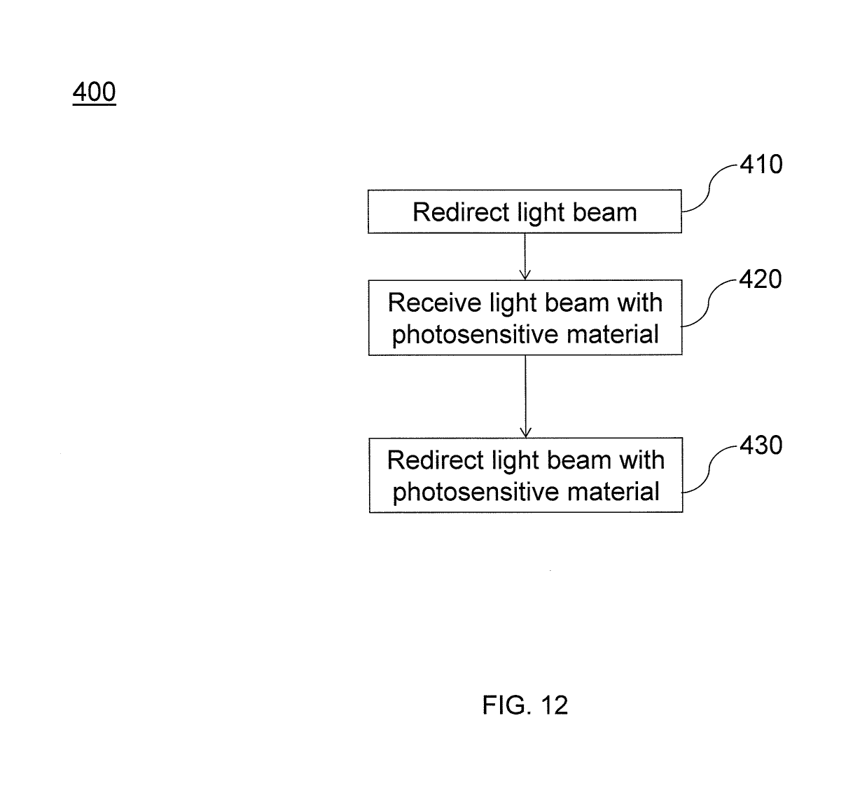

FIG. 12 illustrates an exemplary optical tracking method 400 in accordance with aspects of the present invention. Optical tracking method 400 may be performed by a solar power system. As a general overview, optical tracking method 400 includes redirecting a light beam, receiving the redirected light beam with a photosensitive material, and redirecting the light beam. Additional details of optical tracking method 400 are described herein with respect to optical tracking system 300.

In step 410, a light beam is redirected. In an exemplary embodiment, optical element 310 redirects an incident light beam (e.g., sunlight). The light beam may be redirected by focusing the light beam onto photosensitive material 320 with optical element 310, as shown in FIG. 9, or by reflecting the light beam within the photosensitive material 320 with optical element 310, as shown in FIG. 10.

In step 420, the redirected light beam is received with photosensitive material. In an exemplary embodiment, photosensitive material 320 receives the redirected light beam. Photosensitive material 320 is configured to change its optical properties when it receives the redirected light beam from optical element 310. Photosensitive material 320 may change its optical properties, for example, by the photorefractive effect.

In step 430, the light beam is redirected again. In an exemplary embodiment, photosensitive material 320 redirects the light beam. As explained above, by changing its optical properties when it receives the redirected light beam, photosensitive material 320 is able to continuously track and redirect the light beam regardless of any movement of the light beam.

Optical tracking method 400 is not limited to the above described steps, but may include alternative or additional steps, as would be understood by one of ordinary skill in the art.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. An optical tracking system comprising:
a first optical element configured to focus a light beam; and
a second optical element configured to redirect the focused light beam from the first optical element, the second optical element configured to move in order to continuously receive the focused light beam during movement of the focused light beam.

2. The optical tracking system of claim 1, wherein the second optical element is configured to move via an optical tweezing mechanism generated by the focused light beam.

3. The optical tracking system of claim 2, wherein the second optical element comprises an optical microbead.

4. The optical tracking system of claim 2, further comprising a fluid layer, wherein the second optical element is embedded in the fluid layer.

5. The optical tracking system of claim 1, further comprising a fluid layer,
wherein the second optical element is a bubble generated in the fluid layer by the focused light beam.

6. The optical tracking system of claim 5, wherein the fluid layer comprises water.

7. The optical tracking system of claim 1, further comprising an actuator configured to move the second optical element to continuously receive the focused light beam.

8. The optical tracking system of claim 1, further comprising a path, wherein the second optical element is confined to move along the path.

9. The optical tracking system of claim 8, wherein the path has a curved shape.

10. The optical tracking system of claim 1, further comprising a third optical element configured to focus the redirected light beam from the second optical element.

11. The optical tracking system of claim 10, wherein the second optical element is configured to move such that the focused light beam from the third optical element is continuously directed toward a fixed location.

12. The optical tracking system of claim 11, further comprising a photovoltaic cell positioned at the fixed location.

13. The optical tracking system of claim 10, wherein the first optical element and the third optical element are integrally formed into a single body, and the second optical element is movably contained within the single body.

14. An optical tracking method comprising:
focusing a light beam with a first optical element;
moving a second optical element in order to continuously receive the focused light beam during movement of the focused light beam; and
redirecting the focused light beam with the second optical element.

15. The optical tracking method of claim 14, wherein the moving step comprises moving the second optical element via an optical tweezing mechanism.

16. The optical tracking method of claim 14, further comprising the step of generating the second optical element by directing the focused light beam toward a fluid layer to create a bubble.

17. The optical tracking method of claim 14, wherein the moving step comprises moving the second optical element with an actuator.

18. The optical tracking method of claim 14, further comprising the step of confining the movement of the second optical element to a path.

19. The optical tracking method of claim 14, further comprising the step of focusing or steering the redirected light beam from the second optical element with a third optical element.

20. The optical tracking method of claim 19, further comprising the step of receiving the focused or steered light beam from the third optical element with a photovoltaic cell.

21. The optical tracking method of claim 20, further comprising the step of receiving the focused or steered light beam from the third optical element with an optical collecting element that redirects the light on to the photovoltaic cell.

22. An optical tracking system comprising:
an optical element configured to redirect a light beam; and
a photosensitive material configured to change its optical properties when it receives the redirected light beam from the optical element in order to continuously redirect the light beam during movement of the light beam.

23. The optical tracking system of claim 22, wherein the photosensitive material is configured to change its optical properties via the photorefractive effect.

24. The optical tracking system of claim 23, wherein the photosensitive material comprises a non-linear polymer having an index of refraction that changes as a function of an intensity of incident light.

25. The optical tracking system of claim 22, wherein
the photosensitive material comprises a reflective coating, and
a portion of the photosensitive material expands or contracts as a function of an intensity of incident light in order to create a convex or concave mirror.

26. The optical tracking system of claim 22, further comprising a spherical lens, wherein a portion of the photosensitive material contracts to form a dimple when exposed to the light beam in order to gravitationally trap and actuate the spherical lens.

27. The optical tracking system of claim 22, wherein the optical element is configured to focus or steer the light beam onto the photosensitive material.

28. The optical tracking system of claim 22, wherein the optical element is embedded in the photosensitive material and is configured to reflect the light beam within the photosensitive material.

29. An optical tracking method comprising:
redirecting a light beam with an optical element;
receiving the redirected light beam with a photosensitive material configured to change its optical properties when it receives the redirected light beam; and
redirecting the light beam with the photosensitive material.

30. The optical tracking method of claim 29, wherein the photosensitive material is configured to change its optical properties via the photorefractive effect.

31. The optical tracking method of claim 29, wherein the redirecting step comprises focusing the light beam onto the photosensitive material with the optical element.

32. The optical tracking method of claim 29, wherein the redirecting step comprises reflecting the light beam within the photosensitive material with the optical element.
